(19) United States
(12) Patent Application Publication
(10) Pub. No.: US 2003/0030139 A1
(43) Pub. Date: Feb. 13, 2003

(54) Integral heatsink plastic ball grid array

(76) Inventors: Marcos Karnezos, Palo Alto, CA (US); Bret Zahn, Gilbert, AZ (US); Flynn Carson, Redwood City, CA (US)

Correspondence Address: HAYNES BEFFEL & WOLFELD LLP, P O BOX 366, HALF MOON BAY, CA, 94019, US

(21) Appl. No.: 09/893,356

(22) Filed: Jun. 26, 2001

(51) Int. Cl. H01L 23/34

(52) U.S. Cl. 257/712

(57) ABSTRACT

A plastic ball grid array semiconductor package, employs a large heat spreader, externally attached to the upper surface of the mold cap, to provide improved thermal performance in a thin package format. The plastic ball grid array structure in the package can be constructed substantially as a standard PBGA, although in some embodiments the PBGA has a thinner molding than usual for a standard PBGA, or the wire bonding has a lower loop profile than usual, or the semiconductor device is thinner than usual. The invention can be particularly useful in applications where greater power dissipation is required, or where thin form factors and small footprints are desired.

### BACKGROUND

This invention relates to high performance semiconductor device packaging.

Semiconductor devices increasingly require lower cost packaging with higher thermal and electrical performance. A common package used for high performance devices is the Plastic Ball Grid Array (“PBGA”). The PBGA is a surface mount package that can provide higher thermal and electrical performance, and a lower thickness profile and a smaller footprint, as compared to leadframe based surface mount packages such as Plastic Quad Flat Package (“PQFP”) and others. Improvements are sought in the structure and design of the package, to provide increased thermal and electrical performance and to maintain the established footprint and thickness characteristics of standard PBGAs.

In conventional PBGAs a small fraction of the heat generated by the semiconductor device dissipates to the ambient through the molding compound, principally at the upper surface of the package, and, to a much lesser extent, through the sides. Most of the heat that is generated by the semiconductor device in standard PBGAs is conducted through the solder balls to the product board, and the board acts as a heat sink.

Various approaches have been employed or suggested for increasing power dissipation from PBGAs. For example, power dissipation to the ambient can be increased by blowing air over the package; but cost considerations or space limitations may make such air cooling approaches impractical. And, for example, power dissipation can be increased by increasing the number of solder balls between the package and the board, and, particularly, by increasing the number of balls directly beneath the device; and by using a laminate substrate having multiple metal layers. These approaches require increases in package dimensions and changes in the package structure.

### SUMMARY

According to the invention, improved thermal performance is provided in a PBGA package, by employing a large heat spreader, externally attached to the upper surface of the mold cap, by for example a thin adhesive layer at the upper surface of the mold cap.

In one general aspect the invention features a semiconductor device package including a heat spreader affixed to an upper surface of the mold cap of a PBGA. The PBGA in the package of the invention can be constructed substantially as a standard PBGA, although in some embodiments the PBGA has a thinner molding than usual for a standard PBGA, or the wire bonding has a lower loop profile than usual, or the semiconductor device is thinner than usual. Generally, the PBGA in the package includes a semiconductor device or die mounted onto a surface, conventionally termed the upper surface, of the substrate. The semiconductor device is electrically connected to the substrate, for example by wire bonds; and the semiconductor device and the wire bonds are enclosed by a protective mold material, typically a plastic, which substantially covers among other things at least the upper surface of the semiconductor device. Solder balls are attached to the bottom surface of the substrate, and are reflowed to mount the package onto a product board. The substrate may be provided with electrical traces, pads, vias, and the like to provide electrical connection between the solder balls and the wire bonds—that is, to provide for electrical conduction between particular parts of the product board and the semiconductor device.

In the package according to the invention the heat spreader at the top of the package draws more heat to the top, providing an additional heat transfer path to ambient, and providing for substantially increased power dissipation. The invention may be particularly useful in applications where greater power dissipation is desired or required (as, for example, greater than about 4 watts; such power dissipation may be required or desired in semiconductor graphics applications, for example, or in chipset configurations), and where thin form factors and small footprints are also desired or required.

In some embodiments a portion of the heat spreader lying over the semiconductor device protrudes downward toward the upper surface of the semiconductor device, and the corresponding portion of the mold cap is thinner between the upper surface of the semiconductor device and the heat spreader than more peripherally. Accordingly the heat path from the upper surface of the semiconductor device to ambient includes a lesser proportion of the relatively poorly thermally conductive molding compound, resulting in a reduced thermal resistance along the path. The protruding portion of the heat spreader (also herein termed the mid portion, although it need not be geometrically centered over the semiconductor device) may have any of a variety of forms in plan view, and may have any of a variety of sectional configurations. In some embodiments the mid portion has a generally square or rectangular or round (e.g., circular) shape in plan view, and a generally rectangular or trapezoidal shape in sectional view.

In some embodiments the dimensions (particularly, the thicknesses) of the particular elements of the package are selected so that the overall dimensions of the package are within standard specifications (and, particularly, so that the overall package thickness is about the same as or less than that of standard PBGA packages). Particularly, for example, in some embodiments the thicknesses of the die plus die attach epoxy, the wire bond loop height and the wire-to-mold clearance are determined so that the height from the substrate to the top of the package (that is, the sum of the overall mold cap thickness plus the thickness of the heat spreader and the thickness of the heat spreader adhesive) is no more than 1.17 mm. And, for example, in some embodiments the thicknesses of the portions of elements situated between the semiconductor device and the heat spreader—that is, the elements that lie in the critical thermal path—are determined so as to minimize the length of the critical thermal path.

The invention can provide power dissipation greater than 4 Watts without air cooling, and greater than 5 Watts with air cooling at 100 linear feet per minute, in PBGA devices having standard overall dimensions.

### BRIEF DESCRIPTION OF THE DRAWINGS

FIG. 1 is a diagrammatic sketch in a transverse sectional view thru a conventional plastic ball grid array package.

FIG. 2 is a diagrammatic sketch in a transverse sectional view thru a conventional thermally enhanced plastic ball grid array package.

FIG. 3 is a diagrammatic sketch in a transverse sectional view thru an improved plastic ball grid array package according to an embodiment of the invention.

FIG. 4 is a diagrammatic sketch in a transverse sectional view thru an improved plastic ball grid array package according to another embodiment of the invention.

FIG. 5 is a diagrammatic sketch in a transverse sectional view thru an improved plastic ball grid array package according to still another embodiment of the invention.

FIG. 6 is a diagrammatic sketch in a transverse sectional view thru an improved plastic ball grid array package according to still another embodiment of the invention.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the Figs. illustrating embodiments of the invention, elements corresponding to elements shown in other drawings are not all particularly renumbered, although they are all readily identifiable in all the Figs.

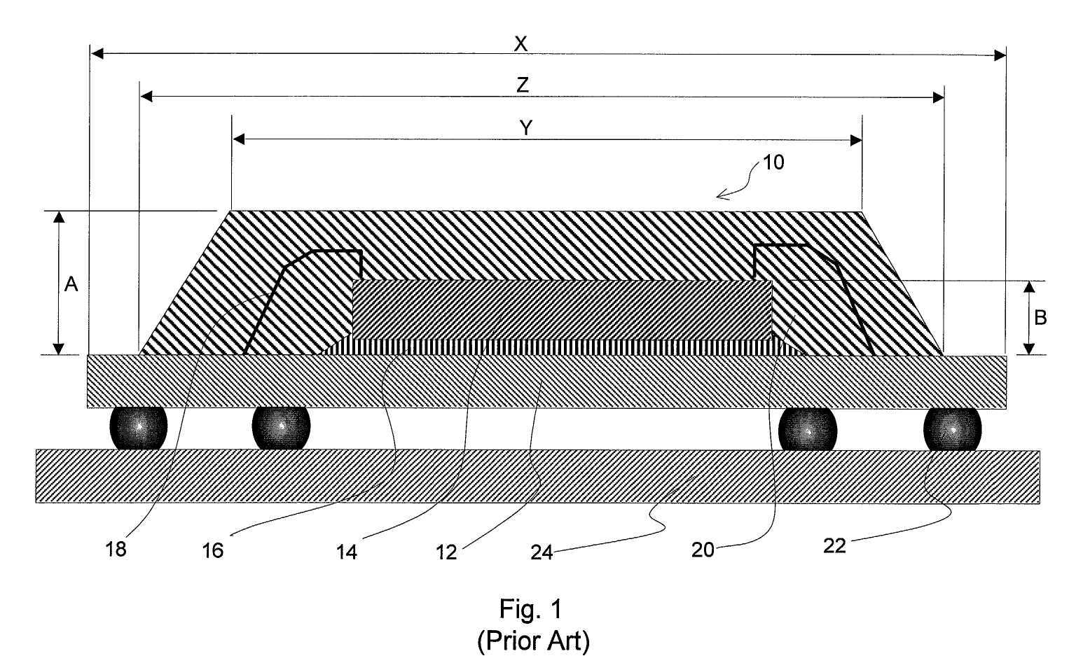

Turning now to FIG. 1, there is shown in a diagrammatic sectional view a conventional or standard PBGA, generally at 10, which includes a semiconductor device (chip) or die 14 affixed by a die attach material 16 such as a die attach epoxy to the upper surface of a laminate substrate 12. Semiconductor device 14 is electrically connected to substrate 12 via wire bonds 18 such as gold wires and molded with molding compound to form a mold cap 20 to protect the device and the wire bonds. Solder balls 22 attached to the bottom of the substrate 12 are electrically connected to the wire bonds through metal traces (not shown in FIG. 1) in the substrate 12. The package 10 can be attached to a product board 24 by reflowing the solder balls 22 to establish electrical and structural connection.

A standard PBGA such as is illustrated in FIG. 1 has a package thickness of 2.33 mm, with a mold cap thickness A of 1.17 mm and a die+die attach epoxy thickness B of 0.38 mm. A standard package body size in common use has a square footprint about 35 mm on each side X, with a mold cap generally in the shape of a truncated square pyramid with chamfered slant edges, having an upper surface dimension Y of 28 mm across and a bottom surface dimension Z of 30 mm across.

The molding compound and the substrate material are relatively poor thermal conductors. The solder balls provide a relatively low resistance heat path from the device to the product board. Heat generated in the semiconductor device of a package such as in FIG. 1 is conducted primarily (about 70% of the total heat transferred) through the substrate and the solder balls to the product board, which serves as a heat sink; and secondarily (less than about 30% of the total) to the ambient through the molding compound at the top; a component of heat is transferred to ambient through the sides of the package but the surface area of the sides is small compared to that of the bottom or top, and this is only a minor fraction of the total heat transferred. Power dissipation from a 35 mm×35 mm PBGA 2.33 mm thick and having 352 solder balls on a two-metal laminate substrate is typically less than 2 Watts in the absence of air flow.

Various approaches to improving power dissipation from a device in such a standard PBGA package are known in the industry. For example, adding 36 solder balls directly beneath the semiconductor device can increase power dissipation to as much as about 2.8 Watts. And increasing the total number of solder balls in the package to 452, including 100 solder balls directly beneath the device, and employing a four-metal laminate substrate can increase power dissipation to as much as about 3.3 Watt. Additionally blowing air over the package at a rate about 100 linear feet per minute (100 lfpm) can increase power dissipation to as much as about 3.6 Waft, but in many applications cost considerations or space constraints (or both cost and space) prevent the use of air cooling. Further increase in power dissipation from such a standard PBGA package can be brought about only with some difficulty, and requires changing the structure of the package.

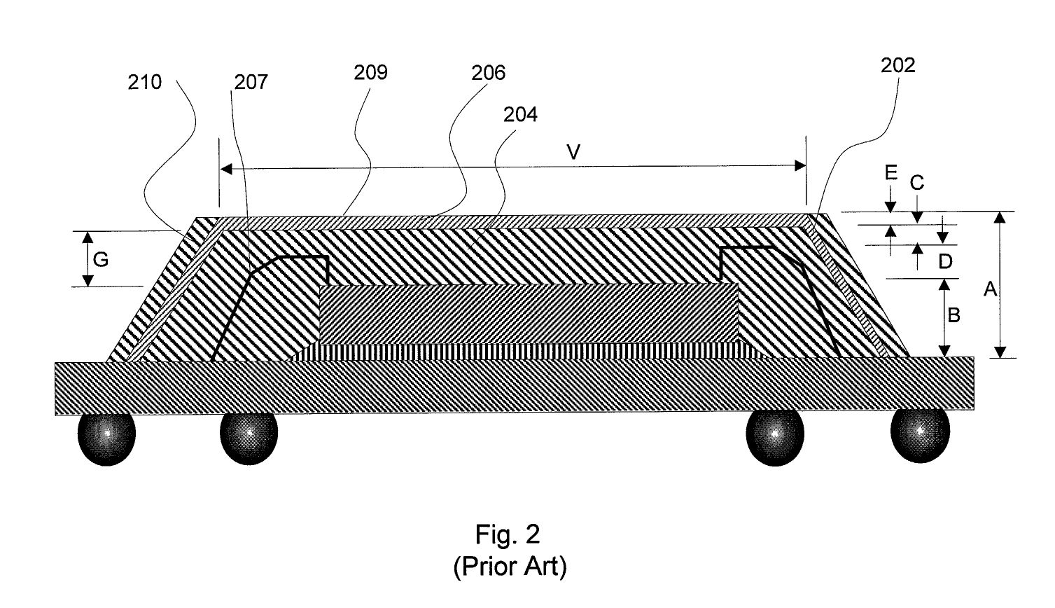

FIG. 2 illustrates a thermally enhanced PBGA package that is widely used in the industry. This structure makes use of a metal heat spreader 202, partially embedded in the molding cap, with embedded portions attached to the substrate, and having a circular upper portion 206 having an upper surface 209 free of molding compound and exposed to the ambient. Such a construct can provide power dissipation to as much as 3.9 Watts with no airflow, and to as much as 4.2 Watts under airflow of 100 lfpm. The improved heat dissipation is a consequence of increased metal content of the package and contributions from particularly two design factors.

One design factor that contributes to improved thermal performance in the PBGA package of FIG. 2 is the reduction of thermal resistance of the path above the device, that is, between the upper surface of the device and the surface of the package, allowing greater heat flow to the top and to the ambient. The thermal resistance of this path is the sum of the thermal resistance of upper portion 206 of the heat spreader adjacent the upper surface 209, having thickness E, and the thermal resistance of the molding compound 204, having thickness G between the upper surface of the device and the undersurface of the upper portion 206 of the heat spreader. Because the thermal conductivity of the metal of which the heat spreader is formed is typically at least 100 times the thermal conductivity of the molding compound, an increase in the proportion of thickness of the metal decreases thermal resistance and increases heat flow from the device to the top of the package. As a practical matter the maximum thickness E of the upper portion 206 of the heat spreader in this configuration is limited to about 0.30 mm by the mold cap thickness A and by the need to accommodate within the thickness of the mold cap the die and die attach epoxy, which have a combined thickness B, as well as the wire loops 207, which extend a dimension D above the upper surface of the die and which must be kept away from contact with the under surface of the upper portion 206 of the heat spreader, by a clearance dimension C. Some heat is conducted to the top by way of the sidewalls 210 of the heat spreader, but this heat path to the device is longer and less conductive. The following dimensions are typical for commonly used thermally enhanced PBGA packages of the kind shown in FIG. 2: mold cap thickness A, 1.17 mm; die+die attach epoxy thickness B, 0.38 mm; wire bond loop height D, 0.33 mm; heat spreader thickness E, 0.30 mm; wire loop clearance C, 0.16 mm.

Another design factor that contributes to improved thermal performance in the PBGA package of FIG. 2 is the exposed circular heat spreader surface 209 which, with a diameter V in widely-used configurations of 22 mm, which conducts more heat to ambient as compared with a surface of molding compound. Heat conduction is generally proportional to the area of the heat spreader surface 209, but as a practical matter the area is limited usually to about 50% of the upper surface of the mold cap.

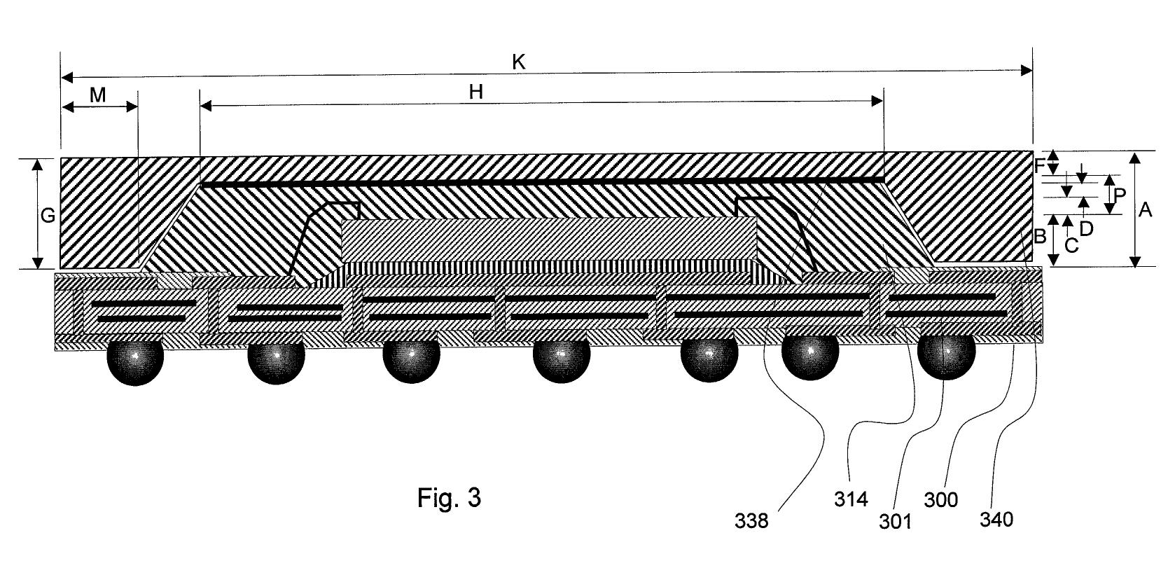

According to the invention, improved thermal performance is provided in a PBGA package, by employing a large heat spreader, externally attached to the upper surface of the mold cap. One illustrative embodiment of the invention is shown diagrammatically in FIG. 3. In this embodiment the PBGA 300 has a thinner mold cap 314 than is standard in the conventional PBGA, and a large heat spreader 340 that substantially covers the whole top of the package; that is, it has an area approximating the area of the footprint of the package. The heat spreader 340 is externally affixed to the upper surface of the mold cap 314 with a thin adhesive 338, so that the entire heat spreader is external to the package, and is not embedded in the mold cap. Peripherally the heat spreader 340 extends down to the substrate and substantially covers the entire surface of the mold cap 340 and the margins of the surface of the substrate adjacent the lower edges of the mold cap, but the heat spreader is not attached to the surface of the substrate.

Table I

| Dimensions (See FIG. 3) | | Example 1 | Example 2 | Example 3 | Example 4 |
|---|---|---|---|---|---|
| Substrate to Package Top | A | 1.17 mm | | | |
| Die + Die Attach Epoxy | B | 0.38 mm | 0.305 mm | 0.255 mm | 0.255 mm |
| Die | | 0.35 mm | 0.275 mm | 0.225 mm | 0.225 mm |
| Wire Bond Loop | C | 0.33 mm | 0.33 mm | 0.33 mm | 0.25 mm |
| Wire-to-Mold Surface Clearance | D | 0.1 mm | | | |
| Heat Spreader Adhesive Thickness | E | 0.025 mm | | | |
| Heat Spreader Thickness at Top | F | 0.335 mm | 0.410 mm | 0.460 mm | 0.540 mm |
| Mold Cap Thickness Overall | L | 0.810 mm | 0.735 mm | 0.685 mm | 0.605 mm |
| Critical Thermal Path | P | 0.455 mm | 0.455 mm | 0.455 mm | 0.375 mm |
| Power (No Airflow) | | 4.50 W | 4.51 W | 4.51 W | 4.66 W |
| Power (100 lfpm) | | 5.10 W | 5.12 W | 5.12 W | 5.31 W |

| | | |
|---|---|---|
| Heat Sink Dimension | K | 34 mm × 34 mm |
| Heat Sink Dimension | H | 27.5 mm × 27.5 mm |
| Heat Sink Margin Width | M | 2.25 mm |
| Heat Sink Thickness at Margin | G | 1.00 mm |

### EXAMPLES 1-4

Four dimensionally different examples of PBGA packages according to the invention having the configuration shown in FIG. 3 were constructed and tested, having the dimensions and thermal performance characteristics listed in Table I.

The total thickness of the package in each of these examples is a standard 2.33 mm. Because the thickness of the molding compound between the upper surface of the die and the under surface of the heat spreader is less than in the conventional configuration, the heat spreader can be made thicker without increasing the overall thickness of the package. As a result there is a higher proportion of metal in the path between the semiconductor device and the upper surface of the package, providing a lower combined thermal resistance along the path from the device to the ambient. The critical heat path thickness P+F is optimized according to the invention by reducing the die thickness and the wire loop height, and increasing F proportionally to maintain the total package thickness.

The power dissipation is higher in each of these examples than in the conventional or standard PBGA packages, as Table I shows.

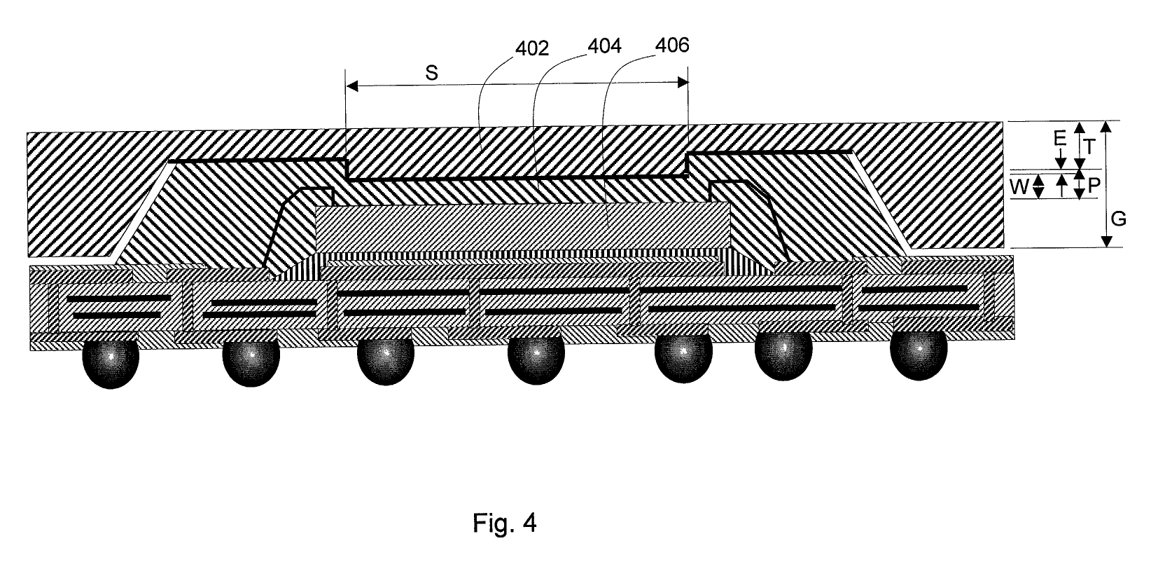

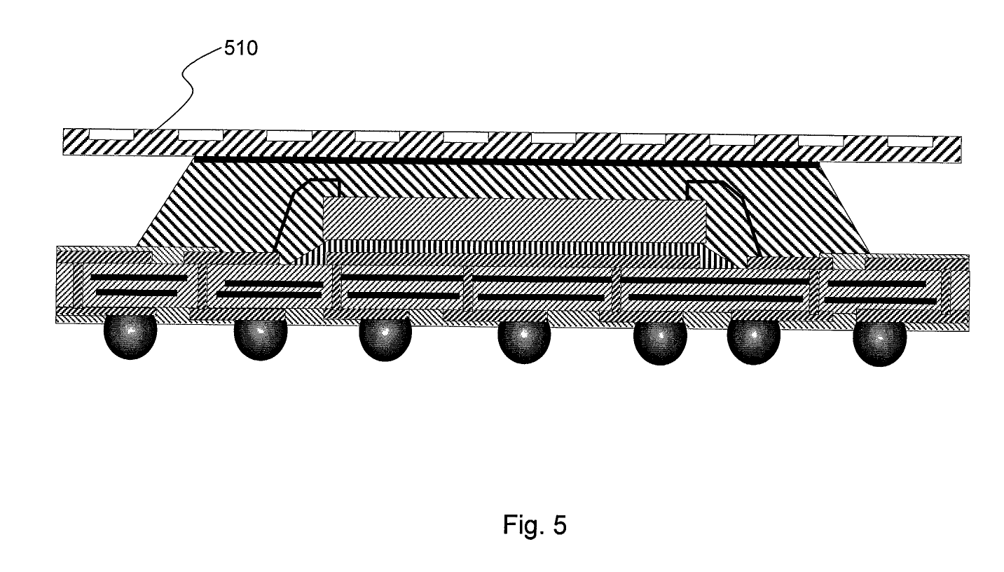

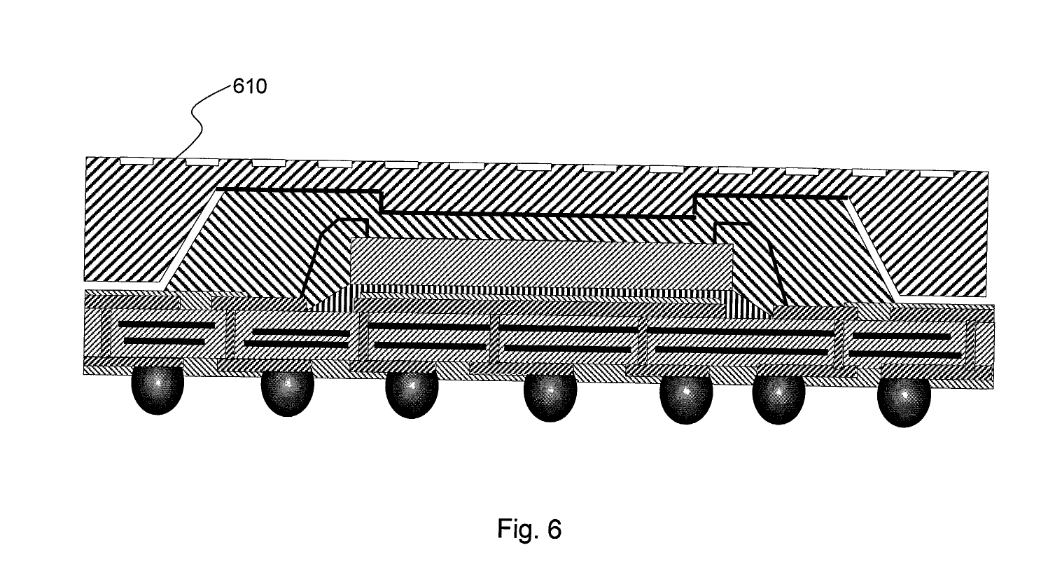

Referring now to FIG. 4, there is shown an alternative embodiment of an improved PBGA package according to the invention. The construction in this embodiment is as in the embodiment of FIG. 3, except that here a mid portion 402 of the heat spreader is made thicker, and a corresponding mid portion 404 of the mold cap is made correspondingly thinner, so that this portion of the heat spreader protrudes toward, but does not contact, the upper surface of the semiconductor device 406. The mid portion may be configured any of a variety of ways, that is, for example, it may be square in a plan view so that the dimension S is the length of a side; or, for example it may be round (e.g., circular) in a plan view so that the dimension S is a diameter. And, for example, the lower extent of the mid portion may not be planar, as it appears in FIG. 4, but, rather, it may be dish shaped, or it may have some other configuration. Typically S can be in a range about 4 mm to about 10 mm, depending upon the die size, and T can be in a range about 0.335 mm to about 0.800 mm, depending upon the die thickness. Preferably the mid portion 402 of the heat spreader is made as wide in plan view as is practicable, but it must not touch the wire bonds and, accordingly, the outer bound of the perimeter of the mid portion 402 of the heat spreader is limited by the locations of the wire bonds. In practice the mold composition and the heat spreader can be readily manufactured to provide a clearance of no less than 0.1 mm between any part of any wire bond and any part of the heat spreader can be achieved; a clearance of about 0.5 mm may be more reliably manufacturable. As may be appreciated, the upper surface of the heat spreader need not be generally planar, as is shown in the Figs.; the protrusion may be formed as a downward concavity, or the heat spreader may be formed with an upwardly convex surface; or, the upper surface of the heat spreader may be given a textured surface to increase the area that presented to ambient, as is shown for example in FIGS. 5 and 6.

In this construction the mold compound within the bounds of the mid portion has a reduced thickness W, and accordingly the thermal resistance of the critical path P is reduced. The reduced thickness of the mid portion 404 of the mold cap may be made as thin as is practicable, so long as the mid portion 402 of the heat spreader does not at any point contact the upper surface of the die. In practice the depression in the mold compound can be readily manufactured to as thin as about 50 μm, although it may be more reliably manufacturable to as thin as 100 μm and a thickness of 150 μm can provide acceptable performance according to the invention.

### EXAMPLES 5-8

Four dimensionally different examples of PBGA packages according to the invention having the configuration shown in FIG. 4 were constructed and tested, having the dimensions and thermal performance characteristics listed in Table II.

The power dissipation is higher in each of these examples than in the conventional or standard PBGA packages, as Table II shows, and can be about 11% higher than in the embodiment of FIG. 3.

Additional alternative embodiments are shown in FIGS. 5 and 6. In the embodiment of FIG. 5 the heat spreader 510 has an area approximating the area of the footprint of the package, and, as in the embodiment of FIG. 3 it is externally affixed to the upper surface of the mold cap with a thin adhesive, so that the entire heat spreader is external to the package, and is not embedded in the mold cap. Here, however, the heat sink is substantially flat and of uniform thickness. There is no downward extension of the periphery of the heat spreader to the substrate, and so the sides of the mold cap and the margins of the surface of the substrate adjacent the lower edges of the mold cap are not enclosed or covered by the heat spreader.

In FIG. 6 the heat spreader 610 is constructed similarly to that of FIG. 3, except that here the area of the upper surface of the heat spreader is treated to significantly increase the surface area by forming channels in one or more orientations on the upper surface where it is exposed to ambient. Similar treatment of the upper surface of the heat spreader is shown in FIG. 5, although it will be appreciated that a flat uniformly thick heat spreader as in the embodiment if FIG. 5 can be made without such surface treatment.

The various components of the package according to the invention can be constructed using conventional materials, and the person of ordinary skill will be able readily to select a material or materials for any particular component or combination of components without undue experimentation. For example, the heat spreader can be made of any suitably thermally conductive material

Table II

| Dimensions (See FIG. 4) | | Example 5 | Example 6 | Example 7 | Example 8 |
|---|---|---|---|---|---|
| Substrate to Package Top | A | 1.17 mm | | | |
| Die + Die Attach Epoxy | B | 0.38 mm | 0.305 mm | 0.255 mm | 0.255 mm |
| Die | | 0.35 mm | 0.275 mm | 0.225 mm | 0.225 mm |
| Wire Bond Loop | C | 0.33 mm | 0.33 mm | 0.33 mm | 0.25 mm |
| Wire-to-Mold Surface Clearance | D | 0.1 mm | | | |
| Heat Spreader Adhesive Thickness | E | 0.025 mm | | | |
| Heat Spreader Thickness at Top | F | 0.335 mm | 0.410 mm | 0.460 mm | 0.540 mm |
| Width (Diameter) of Center | S | 6 mm | | | |
| Extension | | | | | |
| Heat Spreader Thickness over | T | 0.690 mm | | | |
| Center | | | | | |
| Mold Cap Thickness Overall | L | 0.810 mm | 0.735 mm | 0.685 mm | 0.605 mm |
| Critical Thermal Path | P | 0.175 mm | 0.175 mm | 0.175 mm | 0.175 mm |
| Power (No Airflow) | | 4.95 W | 5.01 W | 5.04 W | 5.09 W |
| Power (100 lfpm) | | 5.69 W | 5.78 W | 5.81 W | 5.88 W |

| | | |
|---|---|---|
| Heat Sink Dimension | K | 34 mm × 34 mm |
| Heat Sink Dimension | H | 27.5 mm × 27.5 mm |
| Heat Sink Margin Width | M | 2.25 mm |
| Heat Sink Thickness at Margin | G | 1.00 mm |

Other embodiments are within the following claims.

What is claimed is:

1. A semiconductor device package comprising:
a semiconductor device affixed to an upper surface of a substrate, the semiconductor device having an upper surface;
a mold cap covering at least the upper surface of the semiconductor device, the mold cap having an upper surface;
a heat spreader affixed to at least a portion of the upper surface of the mold cap.

2. The package of claim 1 wherein the semiconductor device is electrically connected to the substrate by wire bonds, and wherein the mold cap covers at least the upper surface of the substrate and the wire bonds.

3. The package of claim 1 wherein a portion of the heat spreader lying overlying the semiconductor device protrudes downward toward the upper surface of the semiconductor device, and a corresponding portion of the mold cap is thinner between the upper surface of the semiconductor device and the heat spreader than more peripherally.

4. The package of claim 3 wherein the downwardly protruding portion of the heat spreader has a generally square shape in plan view.

5. The package of claim 3 wherein the downwardly protruding portion of the heat spreader has a generally rectangular shape in plan view.

6. The package of claim 3 wherein the downwardly protruding portion of the heat spreader has a generally round shape in plan view.

7. The package of claim 3 wherein the downwardly protruding portion of the heat spreader has a generally rectangular shape in transverse sectional view.

8. The package of claim 3 wherein the downwardly protruding portion of the heat spreader has a generally trapezoidal shape in transverse sectional view.

9. The package of claim 1 in which the height from the substrate to the top of the package is less than or equal to about 1.17 mm.
